(19) United States
(12) Patent Application Publication
(10) Pub. No.: US 2026/0107797 A1
(43) Pub. Date: Apr. 16, 2026

(54) INTERCONNECT SUBSTRATE AND METHOD OF MAKING THE SAME

(71) Applicant: SHINKO ELECTRIC INDUSTRIES CO., LTD., Nagano (JP)

(72) Inventor: Keigo SATO, Nagano (JP)

(21) Appl. No.: 19/357,687

(22) Filed: Oct. 14, 2025

(30) Foreign Application Priority Data
Oct. 16, 2024 (JP) 2024-180975

(51) Int. Cl. H01L 23/498; H01L 21/48; H01L 23/00; H01L 23/15

(52) U.S. Cl. CPC H10W 70/635; H10W 70/69; H10W 70/095; H10W 70/692; H10W 74/15; H10W 90/724; H10W 90/734

(57) ABSTRACT

An interconnect substrate includes a core layer made of glass having one surface and another surface, a first through portion penetrating the core layer from the one surface to the another surface, a resin portion covering an inner wall surface of the first through portion, a first laminate including an interconnect layer and an insulating layer and disposed on the one surface of the core layer, and a second through portion penetrating the first laminate and the core layer, wherein the second through portion extends through an inside of the first through portion, and wherein at a position of penetration through the core layer, an inner wall surface of the second through portion is constituted by the resin portion.

### CROSS-REFERENCE TO RELATED APPLICATIONS

The present application is based on and claims priority to Japanese Patent Application No. 2024-180975 filed on October 16, 2024, with the Japanese Patent Office, the entire contents of which are incorporated herein by reference.

### FIELD

The disclosures herein generally relate to interconnect substrates and methods of making an interconnect substrate.

### BACKGROUND

As known in the art, interconnect substrates may have core layers and laminates including interconnect layers and insulating layers alternately laminated on the core layers. In such an interconnect substrate, a through portion may sometimes be formed that extends completely through the core layers and the laminates. The through portion may be used, for example, when identifying the direction of the interconnect substrate or positioning the interconnect substrate.

A core layer made of glass may sometimes be used for an interconnect substrate. In such a case, forming a through portion penetrating the core layer and a laminate creates a high risk of cracking the glass of the core layer, making it difficult to fabricate an interconnect substrate with high reliability.

Accordingly, there may be a need for an interconnect substrate having a through portion penetrating a core layer made of glass and a laminate stacked on the core layer for which cracking of the glass is reduced.

### Related Art Document

### Patent Document

[Patent Document 1] Japanese Laid-open Patent Publication No. 2014-22465

### SUMMARY

According to an aspect of the embodiment, an interconnect substrate includes a core layer made of glass having one surface and another surface, a first through portion penetrating the core layer from the one surface to the another surface, a resin portion covering an inner wall surface of the first through portion, a first laminate including an interconnect layer and an insulating layer and disposed on the one surface of the core layer, and a second through portion penetrating the first laminate and the core layer, wherein the second through portion extends through an inside of the first through portion, and wherein at a position of penetration through the core layer, an inner wall surface of the second through portion is constituted by the resin portion.

The object and advantages of the embodiment will be realized and attained by means of the elements and combinations particularly pointed out in the claims. It is to be understood that both the foregoing general description and the following detailed description are exemplary and explanatory and are not restrictive of the invention, as claimed.

### BRIEF DESCRIPTION OF DRAWINGS

FIGS. 1A and 1B are plan views illustrating an example of an interconnect substrate according to a first embodiment;

FIGS. 2A and 2B are cross-sectional views illustrating the example of the interconnect substrate according to the first embodiment;

FIG. 3 is a drawing illustrating an example of a manufacturing process of the interconnect substrate according to the first embodiment;

FIGS. 4A through 4D are drawings illustrating the example of the manufacturing process of the interconnect substrate according to the first embodiment;

FIGS. 5A through 5C are drawings illustrating the example of the manufacturing process of the interconnect substrate according to the first embodiment;

FIGS. 6A and 6B are plan views illustrating an example of an interconnect substrate according to a variation of the first embodiment;

FIG. 7 is a cross-sectional view illustrating the example of the interconnect substrate according to the variation of the first embodiment; and

FIG. 8 is a cross-sectional view illustrating an example of a semiconductor device according to the second embodiment.

### DESCRIPTION OF EMBODIMENTS

Embodiments of the invention will be described below with reference to the accompanying drawings. In these drawings, the same components are denoted by the same reference numerals, and duplicate descriptions may be omitted.

### <First Embodiment>

### [Structure of Interconnect Substrate of First Embodiment]

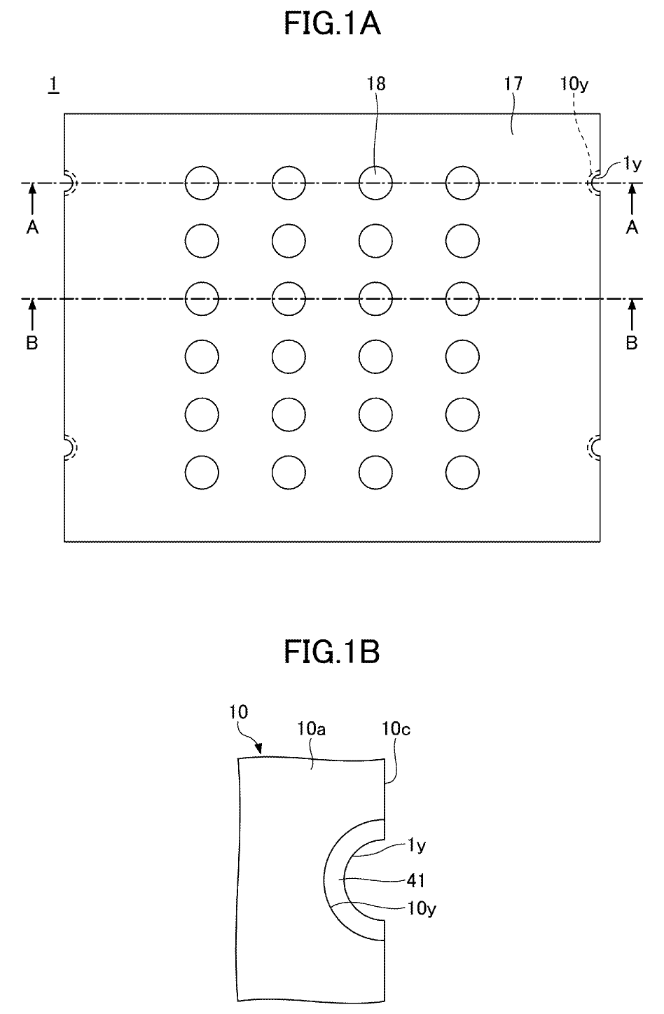

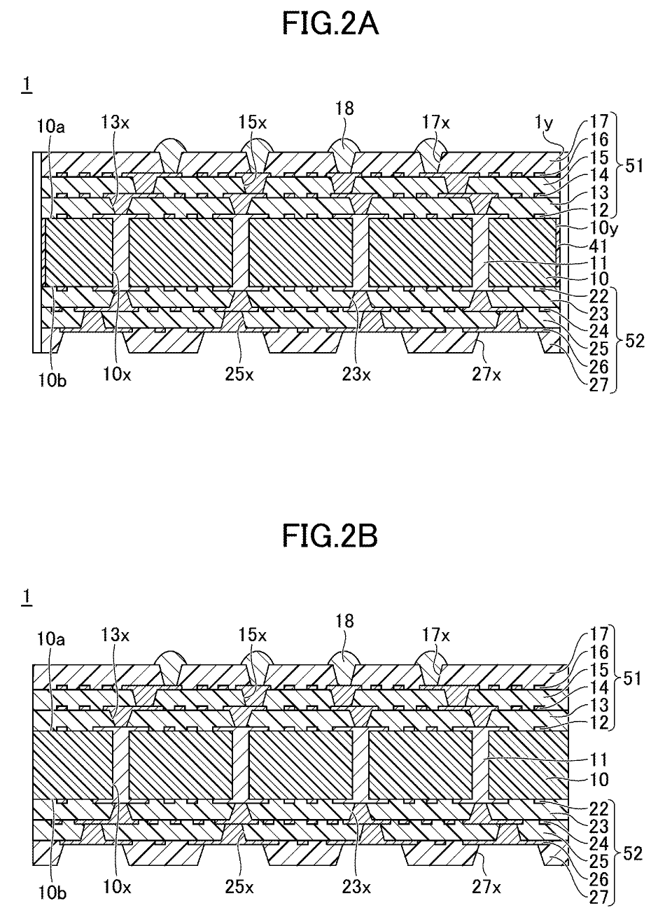

FIGS. 1A and 1B are plan views illustrating an example of an interconnect substrate according to the first embodiment. FIG. 1A is an overall view and FIG. 1B is an enlarged view of a portion around a first through portion 10y of FIG. 1A. It may be noted that in FIG. 1B, the illustration of upper layers above a core layer 10 is omitted. FIGS. 2A and 2B are cross-sectional views illustrating the example of the interconnect substrate according to the first embodiment. FIG. 2A is a cross-sectional view along the line A-A in FIG. 1A and FIG. 2B is a cross-sectional view along the line B-B in FIG. 1A.

Referring to FIGS. 1A and 1B and FIGS. 2A and 2B, the interconnect substrate 1 includes a core layer 10, a first laminate 51 including interconnect layers and insulating layers alternately laminated on a first surface 10a of the core layer 10, and a second laminate 52 including interconnect layers and insulating layers alternately laminated on a second surface 10b of the core layer 10. The interconnect substrate 1 may include external connection terminals 18.

The first laminate 51 includes an interconnect layer 12, an insulating layer 13, an interconnect layer 14, an insulating layer 15, an interconnect layer 16, and a solder resist layer 17 sequentially laminated on the first surface 10a of the core layer 10. The second laminate 52 includes an interconnect layer 22, an insulating layer 23, an interconnect layer 24, an insulating layer 25, an interconnect layer 26, and a solder resist layer 27 sequentially laminated on the second surface 10b of the core layer 10.

In the first embodiment, for convenience, the solder resist layer 17 side of the interconnect substrate 1 is referred to as an upper side or a first side, and the solder resist layer 27 side is referred to as a lower side or a second side. The surface of a portion oriented in the same direction as the solder resist layer 17 side is referred to as a first surface or an upper surface, and the surface of the portion oriented in the same direction as the solder resist layer 27 side is referred to as a second surface or a lower surface. However, the interconnect substrate 1 may be positioned upside down when used, or may be arranged at any angle. The plan view refers to the view of an object as seen from the direction normal to the first surface 10a of the core layer 10, and the plan shape refers to the shape of an object as seen from the direction normal to the first surface 10a of the core layer 10.

The core layer 10 is made of glass. Although the kind of glass constituting the core layer 10 is not limited, alkali-free glass, quartz glass, borosilicate glass, or the like may be used, for example. The thickness of the core layer 10 is, for example, in the range of approximately 100 to 1000 μm. The core layer 10 has through holes 10x that extend through the core layer 10 in the thickness direction. The plan shape of each of the through holes 10x is, for example, circular. The diameter of each of the through holes 10x may be, for example, from 100 μm to 500 μm.

The interconnect substrate 1 includes first through portions 10y each extending from the first surface 10a to the second surface 10b of the core layer 10, and resin portions 41 covering the inner wall surfaces of the first through portions 10y. Each first through portion 10y is a recess recessed inward from a side surface 10c of the core layer 10. The first through portion 10y is, for example, semicircular in plan view. In plan view, the distance from the side surface 10c of the core layer 10 to the deepest portion of the first through portion 10y in the direction perpendicular to the side surface 10c may be, for example, from 0.8 mm to 1.8 mm. Each resin portion 41 is provided along the inner wall surface of a corresponding one of the first through portions 10y and covers the entire inner wall surface. The resin portion 41 is, for example, semicircular in plan view. The material of the resin portion 41 may be, for example, an insulating resin mainly composed of an epoxy-based resin or a polyimide-based resin.

The interconnect substrate 1 has second through portions 1y each penetrating through the first laminate 51, the core layer 10, and the second laminate 52. Each second through portion 1y is a recess recessed inward from the side surfaces of the first laminate 51, the core layer 10, and the second laminate 52. The second through portion 1y extends through the inside of the first through portion 10y, such that the resin portion 41 forms the inner wall surface of the second through portion 1y at the position of penetration through the core layer 10. The second through portion 1y is, for example, a semicircular shape having a smaller diameter than the first through portion 10y in plan view. In plan view, the distance from the side surface 10c of the core layer 10 to the deepest portion of the second through portion 1y in the direction perpendicular to the side surface 10c may be, for example, from 0.5 mm to 1.5 mm.

The interconnect substrate 1 may have at least one set of the first through portion 10y, the resin portion 41, and the second through portion 1y, or may have two or more sets. In the illustrated example, the interconnect substrate 1 has four sets of a first through portion 10y, a resin portion 41, and a second through portion 1y. Two sets of a first through portion 10y, a resin portion 41, and a second through portion 1y are arranged on one of the opposing side surfaces of the interconnect substrate 1 in plan view, and the other two sets are arranged on the other one of the opposing side surfaces of the interconnect substrate 1 in plan view.

The second through portions 1y may be used, for example, when identifying the direction of the interconnect substrate 1 or positioning the interconnect substrate 1. When the interconnect substrate 1 has a plurality of second through portions 1y, the plurality of second through portions 1y are preferably arranged without line symmetry in plan view. This facilitates identifying the direction of the interconnect substrate 1 and positioning the interconnect substrate 1. The second through portions 1y may be used for other purposes in addition to identifying the direction of the interconnect substrate 1 and positioning the interconnect substrate 1.

The interconnect layer 12 is disposed on the first surface 10a of the core layer 10. The interconnect layer 22 is disposed on the second surface 10b of the core layer 10. The interconnect layer 12 and the interconnect layer 22 are electrically connected to each other by through interconnects 11 formed in the through holes 10x. Each of the interconnect layers 12 and 22 is patterned in a predetermined plan shape. The interconnect layers 12 and 22 and the through interconnects 11 may be made of, for example, copper (Cu) or the like. The thicknesses of the interconnect layers 12 and 22 are, for example, in the range of approximately 10 to 40 μm. The interconnect layer 12, the interconnect layer 22, and the through interconnects 11 may be seamlessly formed.

The insulating layer 13 is an interlayer insulating layer disposed on the first surface 10a of the core layer 10 and covering the interconnect layer 12. The insulating layer 13 is also disposed on the upper surface of the resin portion 41. The material of the insulating layer 13 may be, for example, an insulating resin mainly composed of an epoxy-based resin or a polyimide-based resin. The thickness of the insulating layer 13 may be, for example, in the range of approximately 30 to 40 μm. The insulating layer 13 may contain a filler such as silica (SiO₂).

Via holes 13x are formed in the insulating layer 13 to extend through the insulating layer 13 and reach the upper surface of the interconnect layer 12. The via holes 13x may each be an inverted truncated conical hole for which the diameter of the opening toward the insulating layer 15 is larger than the diameter of the opening at the upper surface of the interconnect layer 12.

The interconnect layer 14 is formed on the first side of the insulating layer 13. The interconnect layer 14 includes via interconnects filling the via holes 13x and aninterconnect pattern formed on the upper surface of the insulating layer 13. The interconnect pattern is electrically connected to the interconnect layer 12 throughthe via interconnects. The material of the interconnect layer 14 and the thickness of the interconnect pattern may be substantially the same as those of theinterconnect layer 12, for example.

The insulating layer 15 is formed on the upper surface of the insulating layer 13 so as to cover the interconnect layer 14. The material and the thickness of theinsulating layer 15 may be substantially the same as those of the insulating layer 13, for example. The insulating layer 15 may contain a filler such as silica (SiO₂).

Via holes 15x are formed in the insulating layer 15 to extend through the insulating layer 15 and reach the upper surface of the interconnect layer 14. The via holes 15x may each be an inverted truncated conical hole for which the diameter of the opening toward the solder resist layer 17 is larger than the diameter of the opening at the upper surface of the interconnect layer 14.

The interconnect layer 16 is formed on the first side of the insulating layer 15. The interconnect layer 16 includes via interconnects filling the via holes 15x and pads formed on the upper surface of the insulating layer 15. The pads are electrically connected to the interconnect layer 14 through the via interconnects. The material of the interconnect layer 16 and the thickness of the pads may be substantially the same as those of the interconnect layer 12, for example. The thickness of the pads may be larger than that of the interconnect layer 12. The interconnect layer 16 may also include an interconnect pattern in addition to the pads.

The solder resist layer 17 is a protective insulating layer located as the outermost layer on the first side of the interconnect substrate 1, and is formed on the upper surface of the insulating layer 15 so as to cover the interconnect layer 16. The solder resist layer 17 has openings 17x, and portions of the upper surface of the interconnect layer 16 are exposed within the openings 17x. The plan shape of each of the openings 17x may be, for example, circular. The interconnect layer 16 exposed in the openings 17x may be used, for example, as pads for electrical connections with an electronic component such as a semiconductor chip. The solder resist layer 17 may be formed of, for example, photosensitive epoxy-based insulating resin or acrylic-based insulating resin. The thickness of the solder resist layer 17 is, for example, in the range of approximately 15 to 35 μm.

On the surface of the interconnect layer 16 exposed in the openings 17x, a metal layer may be formed, or an organic coating may be formed by applying an antioxidant treatment such as organic solderability preservative (OSP) treatment. Examples of the metal layer include an Au layer, a Ni/Au layer (a metal layer formed by laminating a Ni layer and an Au layer in this order), a Ni/Pd/Au layer (a metal layer formed by laminating a Ni layer, a Pd layer, and an Au layer in this order), and a Sn layer.

According to need, the external connection terminals 18 may be provided on the interconnect layer 16 exposed in the openings 17x. The external connection terminals 18 are, for example, solder bumps. The material of the solder bumps may be, for example, an alloy containing Pb, an alloy of Sn and Cu, an alloy of Sn and Ag, an alloy of Sn, Ag and Cu, or the like.

The insulating layer 23 is an interlayer insulating layer disposed on the second surface 10b of the core layer 10 and covering the interconnect layer 22. The insulating layer 23 is also disposed on the lower surface of the resin portion 41. The material and the thickness of the insulating layer 23 may be substantially the same as those of the insulating layer 13, for example. The insulating layer 23 may contain a filler such as silica (SiO₂).

Via holes 23x are formed in the insulating layer 23 to extend through the insulating layer 23 and reach the lower surface of the interconnect layer 22. The via holes 23x may each be a truncated conical hole for which the diameter of the opening toward the insulating layer 25 is larger than the diameter of the opening at the lower surface of the interconnect layer 22.

The interconnect layer 24 is formed on the second side of the insulating layer 23. The interconnect layer 24 includes via interconnects filling the via holes 23x and an interconnect pattern formed on the lower surface of the insulating layer 23. The interconnect pattern is electrically connected to the interconnect layer 22 through the via interconnects. The material and the thickness of the interconnect layer 24 may be substantially the same as those of the interconnect layer 12, for example.

The insulating layer 25 is formed on the lower surface of the insulating layer 23 so as to cover the interconnect layer 24. The material and the thickness of the insulating layer 25 may be substantially the same as those of the insulating layer 13, for example. The insulating layer 25 may contain a filler such as silica (SiO₂).

Via holes 25x are formed in the insulating layer 25 to extend through the insulating layer 25 and reach the lower surface of the interconnect layer 24. The via holes 25x may each be a truncated conical hole for which the diameter of the opening toward the solder resist layer 27 is larger than the diameter of the opening at the lower surface of the interconnect layer 24.

The interconnect layer 26 is formed on the second side of the insulating layer 25. The interconnect layer 26 includes via interconnects filling the via holes 25x and an interconnect pattern formed on the lower surface of the insulating layer 25. The interconnect pattern is electrically connected to the interconnect layer 24 through the via interconnects. The material and the thickness of the interconnect layer 26 may be substantially the same as those of the interconnect layer 12, for example.

The solder resist layer 27 is a protective insulating layer located as the outermost layer on the second side of the interconnect substrate 1, and is formed on the lower surface of the insulating layer 25 to cover the interconnect layer 26. The material and thickness of the solder resist layer 27 may be substantially the same as those of the solder resist layer 17, for example. The solder resist layer 27 has openings 27x, and portions of the lower surface of the interconnect layer 26 are exposed within the openings 27x. The plan shape of each of the openings 27x may be, for example, circular. The interconnect layer 26 exposed in the openings 27x may be used as pads for electrical connections to a mounting substrate such as a motherboard. If necessary, a metal layer of the kind previously described may be formed on the lower surface of the interconnect layer 26 exposed in the openings 27x, or an oxidation prevention treatment such as OSP treatment may be applied.

### [Method of Making Interconnect Substrate]

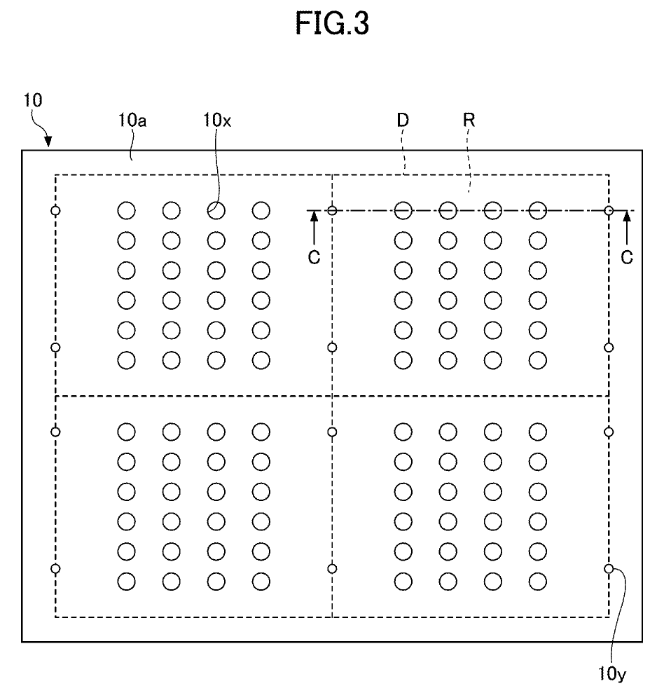

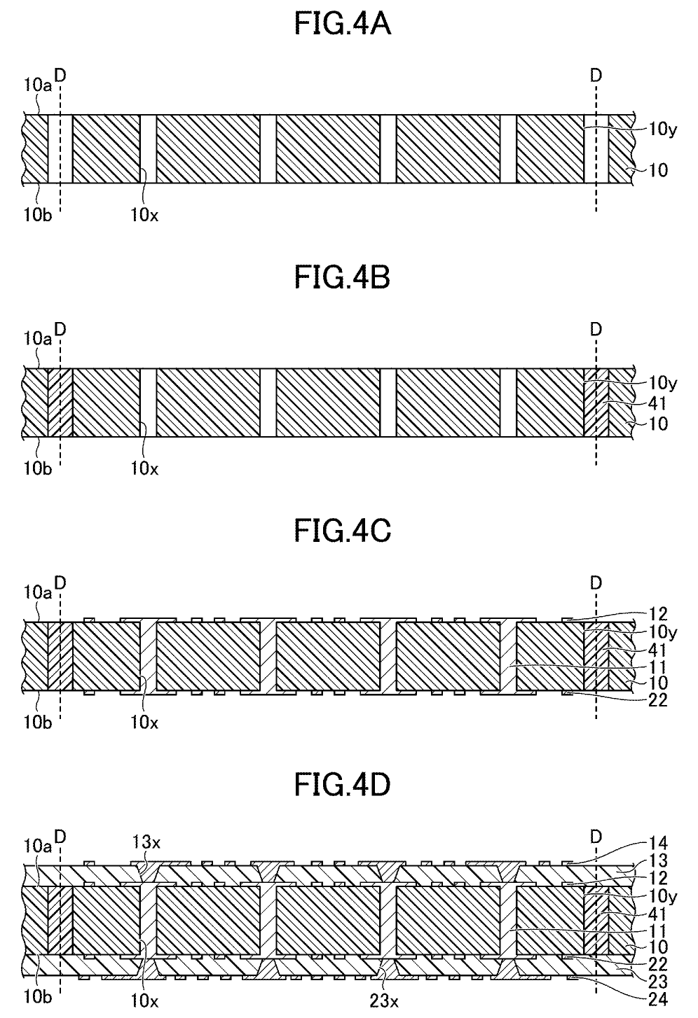

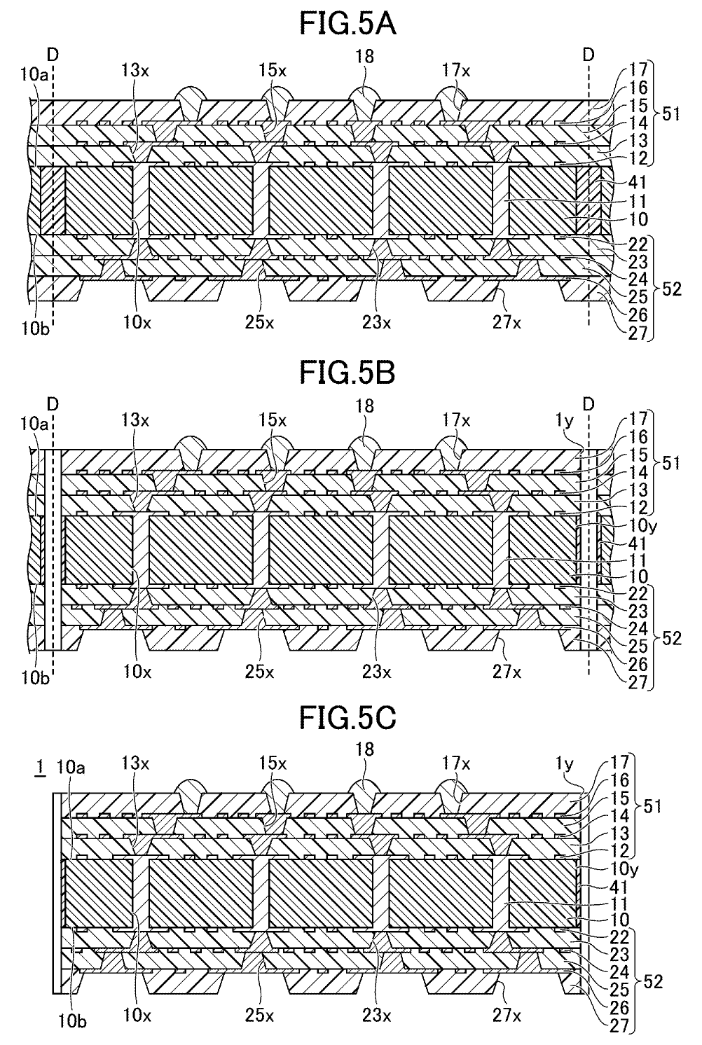

FIG. 3 to FIGS. 5A through 5C are drawings illustrating a manufacturing process of the interconnect substrate according to the first embodiment. FIG. 3 is a plan view, and FIGS. 4A through 4D and FIGS. 5A through 5C are partial cross-sectional views taken along the line C-C in FIG. 3.

First, in the step illustrated in FIGS. 3 and 4A, a core layer 10 made of glass is prepared. The core layer 10 includes a plurality of interconnect regions R for singulation into interconnect substrates, and cutting regions D along which cuts are to be made for singulation. Although the cutting regions D are illustrated as lines in FIGS. 3 and 4A, they may each be a region having a constant width. Next, through holes 10x extending from the first surface 10a to the second surface 10b are formed in the core layer 10 inside each interconnect region R.

Further, first through portions 10y, each straddling a corresponding cutting region D are formed in the core layer 10 so as to extend from the first surface 10a to the second surface 10b. Each first through portion 10y may be, for example, circular in plan view. The diameter of the first through portion 10y may be substantially constant regardless of the position in the depth direction, for example. When a second through portion 1y is formed by drilling in the step illustrated in FIG. 5B, which will be described later, the diameter of the first through portion 10y is set larger than the diameter of the drill used in the step illustrated in FIG. 5B. The diameter of the first through portion 10y may be, for example, from 1.6 mm to 3.6 mm.

The through holes 10x and the first through portions 10y may be formed by wet etching, for example. Examples of the etching solution used in this process include hydrofluoric acid, strong alkali solution, and the like. If the through holes 10x and the first through portions 10y were formed by drilling, there would be a risk that cracks may occur in the glass constituting the core layer 10. However, the use of wet etching enables the formation of the through holes 10x and the first through portions 10y without causing cracks in the glass.

In the step illustrated in FIG. 4B, resin portions 41 for filling the first through portions 10y are formed. The resin portions 41 may be formed, for example, by injecting an uncured thermosetting resin into the first through portions 10y by a printing method or the like, and applying heat for curing. When the resin portions 41 protrude from the first surface 10a and/or the second surface 10b, polishing may be performed to make the upper surface of the resin portions 41 and the first surface 10a flush with each other, and to make the lower surface of the resin portions 41 and the second surface 10b flush with each other.

In the steps illustrated in FIGS. 4C through 5A, a first laminate 51 including alternately laminated interconnect layers and insulating layers is formed on the first surface 10a of the core layer 10. Further, a second laminate 52 including alternately laminated interconnect layers and insulating layers is formed on the second surface 10b of the core layer 10. Specifically, as illustrated in FIG. 4C, an interconnect layer 12 is disposed in each interconnect region R on the first surface 10a of the core layer 10, and an interconnect layer 22 is disposed in each interconnect region R on the second surface 10b of the core layer 10, with through interconnects 11 formed in the through holes 10x. For example, a seed layer (copper or the like) covering the first surface 10a, the second surface 10b of the core layer 10, and the inner wall surfaces of the through holes 10x is formed by an electroless plating method, a sputtering method, or the like, and an electroplating layer (copper or the like) is formed on the seed layer by an electroplating method using the seed layer as a current supply path. This arrangement fills the through holes 10x with the electrolytic plating layer formed on the seed layer, and forms the conductive layers each as a laminate of the seed layer and the electrolytic plating layer on the first surface 10a and the second surface 10b of the core layer 10. Thereafter, the conductor layers are patterned into predetermined plan shapes by a subtractive method or the like to form the interconnect layers 12 and 22.

As illustrated in FIG. 4D, insulating layers 13 and 23 and interconnect layers 14 and 24 are formed. First, the insulating layer 13 covering the upper surfaces of the interconnect layer 12 and the resin portions 41 is disposed in each interconnect region R and each cutting region D on the first surface 10a of the core layer 10. Specifically, for example, a semi-cured epoxy-based resin film or the like is laminated on the first surface 10a of the core layer 10 so as to cover the interconnect layer 12 and the resin portions 41, and then cured to form the insulating layer 13. Alternatively, instead of laminating epoxy-based resin film or the like, epoxy-based resin or the like in liquid or paste form may be applied and then cured to form the insulating layer 13. The material and the thickness of the insulating layer 13 are as previously described. Similarly, the insulating layer 23 covering the lower surfaces of the interconnect layer 22 and the resin portions 41 is disposed in each interconnect region R and each cutting region D on the second surface 10b of the core layer 10.

Next, via holes 13x are formed in the insulating layer 13 to penetrate the insulating layer 13 and expose the upper surface of the interconnect layer 12. Also, via holes 23x are formed in the insulating layer 23 to penetrate the insulating layer 23 and expose the lower surface of the interconnect layer 22. The via holes 13x and 23x may be formed by a laser processing method using, for example, a CO₂ laser. After the via holes 13x and 23x are formed, desmearing treatment is preferably performed to remove resin residues adhering to the surfaces of the interconnect layers 12 and 22 exposed at the end of the via holes 13x and 23x.

The interconnect layer 14 is then formed on the first side of the insulating layer 13. The interconnect layer 14 includes via interconnects filling the via holes 13x and an interconnect pattern formed on the upper surface of the insulating layer 13. The interconnect layer 14 is electrically connected to the interconnect layer 12 exposed at the bottom of the via holes 13x. Similarly, the interconnect layer 24 is formed on the second side of the insulating layer 23. The interconnect layer 24 includes via interconnects filling the via holes 23x and an interconnect pattern formed on the lower surface of the insulating layer 23. The interconnect layer 24 is electrically connected to the interconnect layer 22 exposed at the end of the via holes 23x. The materials of the interconnect layers 14 and 24 and the thicknesses of the interconnect patterns may be the same as those of the interconnect layer 12, for example. The interconnect layers 14 and 24 are formed, for example, by a semi-additive method.

As illustrated in FIG. 5A, insulating layers 15 and 25, interconnect layers 16 and 26, solder resist layers 17 and 27, and external connection terminals 18 are formed. First, the same steps as those of FIG. 4D are repeated to form the insulating layers 15 and 25 and the interconnect layers 16 and 26. Next, the solder resist layer 17 is formed on the upper surface of the insulating layer 15 so as to cover the interconnect layer 16. Further, the solder resist layer 27 is formed on the lower surface of the insulating layer 25 so as to cover the interconnect layer 26. The solder resist layer 17 may be formed, for example, by applying a photosensitive epoxy-based insulating resin in liquid or paste form to the upper surface of the insulating layer 15 so as to cover the interconnect layer 16 by screen printing, roll coating, spin coating, or the like. Alternatively, a photosensitive epoxy-based insulating resin film, for example, may be laminated on the upper surface of the insulating layer 15 so as to cover the interconnect layer 16. The method of forming the solder resist layer 27 is substantially the same as that of the solder resist layer 17. Thereafter, the solder resist layers 17 and 27 are exposed and developed. As a result, openings 17x are formed through the solder resist layer 17 to expose the interconnect layer 16. Also, openings 27x for exposing portions of the lower surface of the interconnect layer 26 are formed in the solder resist layer 27. According to need, the external connection terminals 18 may be provided on the interconnect layer 16 exposed in the openings 17x. The external connection terminals 18 are, for example, solder bumps formed by solder reflow or the like.

In the step illustrated in FIG. 5B, second through portions 1y extending through the first laminate 51, the resin portions 41, and the second laminate 52 are formed. For example, the second through portions 1y are formed such that the centers of the second through portions 1y are substantially aligned with the centers of the resin portions 41 and the centers of the first through portions 10y in plan view. Each second through portion 1y may be, for example, a circular shape having a diameter smaller than that of the first through portion 10y in plan view. The diameter of the second through portion 1y may be, for example, substantially constant regardless of the position in the depth direction. The diameter of the second through portion 1y may be, for example, from 1 mm to 3 mm. The second through portion 1y may be formed by, for example, drilling. Each resin portion 41 has become, for example, annular in plan view, and the inner wall surface of the second through portion 1y is constituted by the resin portion 41 at the position of penetration through the core layer 10.

In the step illustrated in FIG. 5C, the first laminate 51, the core layer 10, and the second laminate 52 are cut along the cutting regions D illustrated in FIG. 5B to produce a plurality of singulated interconnect substrates 1. The cutting may be performed by, for example, a dicer. By cutting along the cutting regions D, each second through portion 1y, which is circular in plan view, is divided into semicircular shapes in plan view, and exposed on the side surfaces of the respective singulated interconnect substrates 1. In addition, each resin portion 41, which is annular in plan view, is divided into semi-annular shapes in plan view, so that the inner wall surface of the second through portion 1y is formed by the resin portion 41 at the position of penetration through the core layer 10.

As described above, the manufacturing method of the interconnect substrate 1 is such that the first through portions 10y are formed in advance through the core layer 10 made of glass by a method such as etching that is unlikely to cause cracks, and the first through portions 10y are filled with the resin portions 41. Further, after the first laminate 51 is formed on the first surface 10a of the core layer 10 and the second laminate 52 is formed on the second surface 10b of the core layer 10, the second through portions 1y are formed to extend through the first laminate 51, the resin portions 41 of the core layer 10, and the second laminate 52. The second through portions 1y penetrate the resin portions 41, but do not penetrate the glass constituting the core layer 10, so that cracks do not occur in the glass. That is, this arrangement reduces cracking in the glass of the core layer 10 in the interconnect substrate 1.

### <Variation of First Embodiment>

A variation of the first embodiment is directed to an example in which the positions and the like of the first through portions, the resin portions, and the second through portions are different than in the interconnect substrate of the first embodiment. In connection with the variation of the first embodiment, descriptions of the same components as those of the already described embodiment may be omitted.

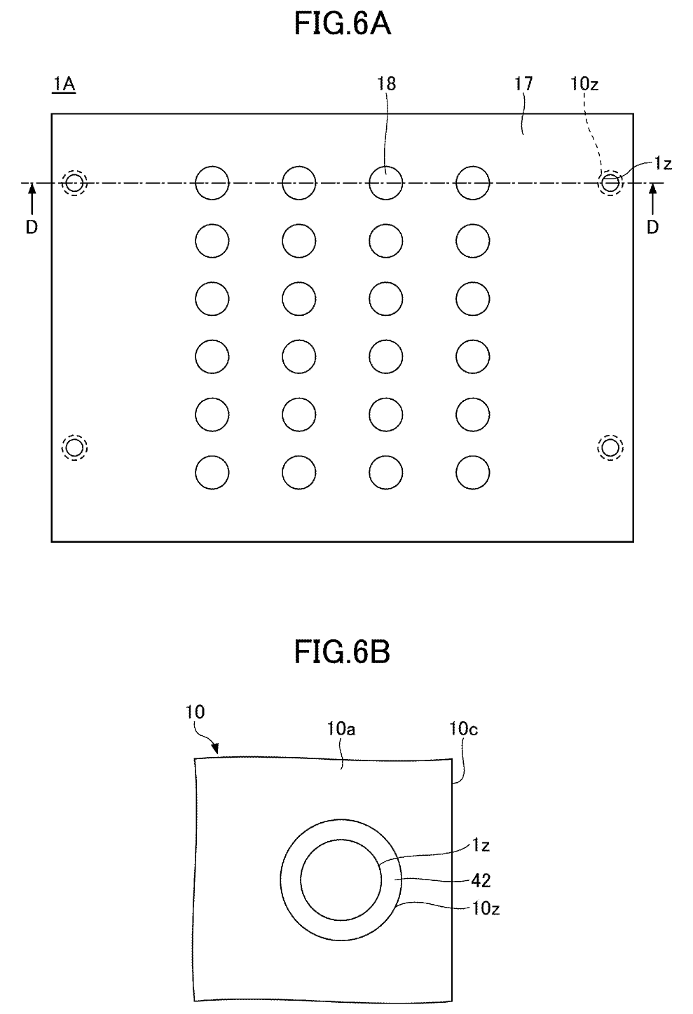

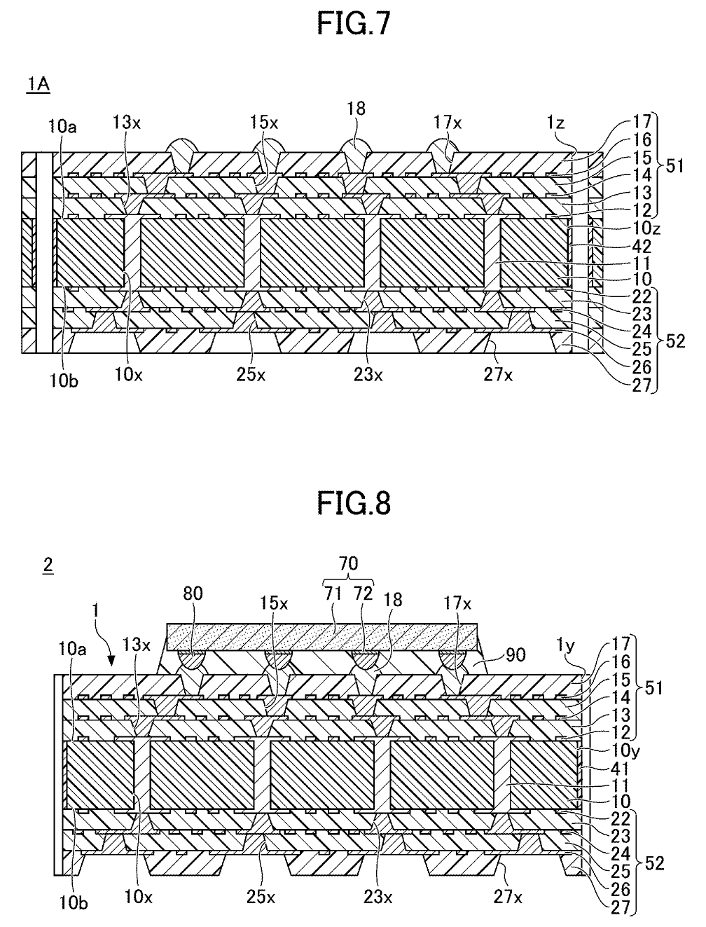

FIGS. 6A and 6B are plan views illustrating an example of an interconnect substrate according to the variation of the first embodiment. FIG. 6A is an overall view and FIG. 6B is an enlarged view of a portion around a first through portion 10z in FIG. 6A. It may be noted that in FIG. 6B, the illustration of upper layers above the core layer 10 is omitted. FIG. 7 is a cross-sectional view illustrating the example of the interconnect substrate according to the variation of the first embodiment, and illustrates a cross-sectional view taken along the line D-D in FIG. 6A.

Referring to FIGS. 6A and 6B and FIG. 7, an interconnect substrate 1A is such that the core layer 10 has first through portions 10z, which are through holes extending from the first surface 10a to the second surface 10b, and resin portions 42 covering the inner wall surfaces of the first through portions 10z. Each first through portion 10z is, for example, circular in plan view. The diameter of the first through portion 10z may be, for example, from 1.6 mm to 3.6 mm.

A resin portion 42 is provided on the inner wall surface of each first through portion 10z and covers the entire inner wall surface. The resin portion 42 is, for example, annular in plan view. The material and the thickness of the resin portion 42 may be, for example, substantially the same as those of the resin portion 41. Unlike the interconnect substrate 1, the first through portion 10z and the resin portion 42 are not exposed on the side surface 10c of the interconnect substrate 1A.

The interconnect substrate 1A has second through portions 1z, each of which is a through hole penetrating the first laminate 51, the core layer 10, and the second laminate 52. Each second through portion 1z extends through the inside of a corresponding first through portion 10z, such that the resin portion 42 forms the inner wall surface of the second through portion 1z at the position of penetration through the core layer 10. The second through portion 1z is, for example, a circular shape having a smaller diameter than the first through portion 10z in plan view. The second through portion 1z may be, for example, provided concentrically with the first through portion 10z in plan view. The diameter of the second through portion 1z may be, for example, from 1 mm to 3 mm. Unlike the interconnect substrate 1, the second through portion 1z is not exposed on the side surface 10c of the interconnect substrate 1A.

The first through portions 10z, the resin portions 42, and the second through portions 1z are effectively prevented from being exposed on the side surfaces of the singulated interconnect substrate 1A by forming the first through portions 10z in the interconnect region R at the positions not overlapping with the cutting regions D in the step corresponding to FIGS. 3 and 4A of the first embodiment, for example.

In this manner, the second through portions 1z extend through the resin portions 42, but do not penetrate the glass of the core layer 10, so that cracks do not occur in the glass. That is, this arrangement reduces cracking in the glass of the core layer 10 in the interconnect substrate 1A.

### <Second Embodiment>

The second embodiment is directed to an example of a semiconductor device in which a semiconductor chip is mounted on the interconnect substrate according to the first embodiment. It may be noted that, in connection with the second embodiment, descriptions of the same components as those in the already described embodiment may be omitted.

FIG. 8 is a cross-sectional view illustrating an example of a semiconductor device according to the second embodiment. Referring to FIG. 8, a semiconductor device 2 includes the interconnect substrate 1 illustrated in FIGS. 1A and 1B, a semiconductor chip 70, bumps 80, and an underfill resin 90.

The semiconductor chip 70 includes a chip 71 and electrodes 72. The chip 71 is configured such that a semiconductor integrated circuit (not illustrated) or the like is formed on a thin semiconductor substrate (not illustrated) made of, for example, silicon. The electrodes 72 electrically connected to the semiconductor integrated circuit are formed on the semiconductor substrate (not illustrated).

The bumps 80 are formed on the electrodes 72 of the semiconductor chip 70, and electrically connects the electrodes 72 and the external connection terminals 18 of the interconnect substrate 1. The electrodes 72 may be formed of, for example, copper. The bumps 80 may be, for example, solder bumps. The material of the solder bumps may be, for example, an alloy containing Pb, an alloy of Sn and Cu, an alloy of Sn and Ag, an alloy of Sn, Ag and Cu, or the like. The underfill resin 90 fills a gap between the semiconductor chip 70 and the upper surface of the solder resist layer 17 of the interconnect substrate 1.

In this manner, the fabrication of the semiconductor device is effectively achieved by mounting the semiconductor chip on the interconnect substrate according to the first embodiment. The interconnect substrate 1A may be used instead of the interconnect substrate 1.

According to the disclosed technology, an interconnect substrate is provided that has a through portion penetrating a core layer made of glass and a laminate stacked on the core layer, and that effectively reduces cracking of the glass.

Although the preferred embodiments have been described in detail, the present invention is not limited to these embodiments, and various modifications and substitutions may be made to the above-described embodiments without departing from the scope of the appended claims.

For example, the above-described embodiments are directed to the interconnect substrate that has the first laminate on the first surface of the core layer made of glass and the second laminate on the second surface. However, the present invention may be applied to an interconnect substrate having the first laminate on the first surface of the core layer made of glass and not having the second laminate on the second surface, while providing substantially the same advantageous effects. When the interconnect substrate does not have a second laminate, the interconnect substrate has second through portions penetrating the first laminate and the core layer, and the second through portions extend through the inside of the first through portions. At the positions of penetration through the core layer, the inner wall surfaces of the second through portions are defined by the resin portions. In the case where the interconnect substrate does not have the second laminate, the through holes may not be provided in the core layer.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present inventions have been described in detail, it should be understood that the various changes, substitutions, and alterations could be made hereto without departing from the spirit and scope of the invention.

The present disclosures non-exhaustively contain the subject matter set out in the following clauses.

[Clause 1] A method of making an interconnect substrate, comprising: providing a glass core layer having a plurality of interconnect regions for singulation into interconnect substrates and cutting regions along which cuts are to be made for the singulation; forming first through portions each penetrating the core layer from one surface thereof to another surface thereof; forming resin portions to fill the first through portions; forming a first laminate including an interconnect layer and an insulating layer on the one surface of the core layer; and forming second through portions each penetrating the first laminate and the resin portion, wherein at a position of penetration through the core layer, inner wall surfaces of the second through portions are constituted by the resin portions.

[Clause 2] The method according to clause 1, wherein the first through portions, the second through portions, and the resin portions are each formed so as to straddle a corresponding one of the cutting regions, the method further comprising, after the forming the second through portions, producing a plurality of singulated interconnect substrates by cutting the first laminate and the core layer along the cutting regions, wherein the second through portions are exposed on side surfaces of the singulated interconnect substrates, and the inner wall surfaces of the second through portions at a position of penetration through the core layer are constituted by the resin portions.

[Clause 3] The method according to clause 1, wherein the first through portions are formed in the interconnect regions so as not to be in contact with the cutting regions.

[Clause 4] The method according to clause 1, wherein the first through portions are formed by wet etching, and the second through portions are formed by drilling.

[Clause 5] The method according to clause 1, wherein the forming the first through portions includes forming through holes each penetrating the core layer from the one surface to the another surface, simultaneously with the forming of the first through portions, the method further comprising forming through interconnects in the through holes after the forming of the resin portions.

[Clause 6] The method according to clause 1, further comprising forming a second laminate including an interconnect layer and an insulating layer on the another surface of the core layer before the forming of the second through portions, wherein the second through portions penetrate the first laminate, the core layer, and the second laminate.

What is claimed is:

1. An interconnect substrate comprising:
a core layer made of glass having one surface and another surface;
a first through portion penetrating the core layer from the one surface to the another surface;
a resin portion covering an inner wall surface of the first through portion;
a first laminate including an interconnect layer and an insulating layer and disposed on the one surface of the core layer; and
a second through portion penetrating the first laminate and the core layer,
wherein the second through portion extends through an inside of the first through portion, and
wherein at a position of penetration through the core layer, an inner wall surface of the second through portion is constituted by the resin portion.

2. The interconnect substrate according to claim 1, wherein the first through portion is a groove recessed inward from a side surface of the core layer, and the second through portion is a groove recessed inward from a side surface of the first laminate and the side surface of the core layer.

3. The interconnect substrate according to claim 1, wherein the first through portion is a through hole penetrating the core layer, and the second through portion is a through hole penetrating the first laminate and the core layer.

4. The interconnect substrate according to claim 1, further comprising a second laminate including an interconnect layer and an insulating layer and disposed on the another surface of the core layer,
wherein the second through portion penetrates the first laminate, the core layer, and the second laminate.
